(19) United States
(12) Patent Application Publication
(10) Pub. No.: US 2024/0397796 A1
(43) Pub. Date: Nov. 28, 2024

(54) DISPLAY PANEL AND DISPLAY DEVICE

(71) Applicant: Hubei Yangtze Industrial Innovation Center Of Advanced Display Co., Ltd., Wuhan (CN)

(72) Inventor: Xiaoyang TONG, Wuhan (CN)

(21) Appl. No.: 18/795,166

(22) Filed: Aug. 5, 2024

(30) Foreign Application Priority Data
Mar. 5, 2024 (CN) 202410253195.4

(51) Int. Cl. H10K 59/80; H10K 59/122

(52) U.S. Cl. CPC H10K 59/873; H10K 59/122

(57) ABSTRACT

A display panel and a display device are provided. The display panel includes a display region and a non-display region surrounding the display region. The display panel includes an encapsulation structure including an organic material, and the organic material covers the display region in a thickness direction of the display panel. The non-display region is provided with a barrier structure and a first electrode, the barrier structure overlaps with the first electrode in the thickness direction of the display panel. The barrier structure includes a first portion located at a side of the first electrode facing a light-exiting surface of the display panel, and the first portion includes a hollow region, in which the first electrode is exposed. Whether the organic material overflows is visually observed by observing retroreflective brightness of the first electrode in the hollow region, to monitor the overflow situation of the organic material.

### CROSS-REFERENCE TO RELATED APPLICATIONS

The present application claims priority to Chinese Patent Application No. 202410253195.4, filed on Mar. 5, 2024, the content of which is incorporated herein by reference in its entirety.

### TECHNICAL FIELD

The present disclosure relates to the field of display technology, and in particular, to a display panel and a display device.

### BACKGROUND

In the related art, some display panels use black pixel definition layers to reduce the reflectivity of external ambient light. A barrier structure located at a periphery of the display region usually includes the same material as the pixel definition layer, resulting in that the barrier structure also includes a black portion. When an encapsulation material overflows to the barrier structure, a color change at the barrier structure cannot be visually recognized, resulting in difficulty in detecting an overflow situation of the encapsulation material. Therefore, a solution is urgently desired.

### SUMMARY

In view of this, embodiments of the present disclosure provide a display panel and a display device, aiming to solve the above-mentioned problems.

In an aspect, embodiments of the present disclosure provide a display panel, including a display region and a non-display region surrounding the display region. The display panel includes an encapsulation structure including an organic material, and the organic material covers the display region in a thickness direction of the display panel. The non-display region is provided with a barrier structure and a first electrode, the barrier structure overlaps with the first electrode in the thickness direction of the display panel. The barrier structure includes a first portion located at a side of the first electrode facing a light-exiting surface of the display panel, and the first portion includes a hollow region, in which the first electrode is exposed.

In another aspect, the embodiments of the present disclosure provides a display device including a display panel. The display panel includes a display region and a non-display region surrounding the display region. The display panel includes an encapsulation structure including an organic material, and the organic material covers the display region in a thickness direction of the display panel. The non-display region is provided with a barrier structure and a first electrode, the barrier structure overlaps with the first electrode in the thickness direction of the display panel. The barrier structure includes a first portion located at a side of the first electrode facing a light-exiting surface of the display panel, and the first portion includes a hollow region, in which the first electrode is exposed.

In the embodiments of the present disclosure, the first electrode is arranged to be exposed in the hollow region of the first portion. In this case, when the organic material overflows to the position of the hollow region of the barrier structure, in the hollow region, the film layer at a side of the first electrode facing the light-exiting surface of the display panel changes, the first electrode has different retroreflective brightness. Thus, the overflow situation of the organic material can be visually observed, thereby achieving an effect of monitoring of the overflow situation of the organic material.

### BRIEF DESCRIPTION OF DRAWINGS

In order to better illustrate technical solutions in embodiments of the present disclosure, the accompanying drawings used in the embodiments are briefly introduced as follows. It should be noted that the drawings described as follows are merely part of the embodiments of the present disclosure, and other drawings can also be acquired by those skilled in the art without paying creative efforts.

FIG. 1 is a schematic plan view of a display panel according to an embodiment of the present disclosure;

FIG. 2 is a schematic structural view of the display panel according to an embodiment of the present disclosure;

FIG. 3 is a partial plan view of a first non-display region in FIG. 1;

FIG. 4 is another partial plan view of the first non-display region in FIG. 1;

FIG. 5 is another partial plan view of the first non-display region in FIG. 1;

FIG. 6 is another partial plan view of the first non-display region in FIG. 1;

FIG. 7 is a schematic view of a barrier structure according to an embodiment of the present disclosure;

FIG. 8 is another partial plan view of the first non-display region in FIG. 1;

FIG. 9 is another partial plan view of the first non-display region in FIG. 1;

FIG. 10 is another partial plan view of the first non-display region in FIG. 1;

FIG. 11 is a schematic view of another barrier structure according to an embodiment of the present disclosure; and

FIG. 12 is a schematic view of a display device according to an embodiment of the present disclosure.

### DESCRIPTION OF EMBODIMENTS

In order to better illustrate technical solutions of the present disclosure, the embodiments of the present disclosure are described in details in the following with reference to the accompanying drawings.

It should be clear that the described embodiments are merely some of, rather than all of the embodiments of the present disclosure. All other embodiments obtained by those skilled in the art without creative efforts shall fall into a scope of the present disclosure.

The terms used in the embodiments of the present disclosure are merely for the purpose of describing particular embodiments but not intended to limit the present disclosure. Unless otherwise noted in the context, the singular form expressions “a”, “an”, “the” and “said” used in the embodiments and appended claims of the present disclosure are also intended to represent plural form expressions thereof.

It should be understood that the term “and/or” used herein is merely an association relationship describing associated objects, indicating that there may be three relationships, for example, A and/or B may indicate that three cases, i.e., A existing individually, A and B existing simultaneously, B existing individually. In addition, the character “/” herein generally indicates that the related objects before and after the character form an “or” relationship.

In the description of this specification, it should be understood that the terms “substantially”, “basically” “approximately”, “about”, “almost” and “roughly” described in the claims and embodiments of the present disclosure indicates a value that can be generally agreed within a reasonable process operation range or tolerance range, rather than an exact value.

It should be understood that although the direction, barrier, hollow region, etc., may be described using the terms of “first”, “second”, etc., in the embodiments of the present disclosure, the direction, barrier, hollow region, etc., will not be limited to these terms. These terms are merely used to distinguish the directions, barriers, hollow regions, etc., from one another. For example, without departing from the scope of the embodiments of the present disclosure, a first direction may also be referred to as a second direction, similarly, a second direction may also be referred to as a first direction.

The present disclosure provides solutions to the problems existing in the related art as follows.

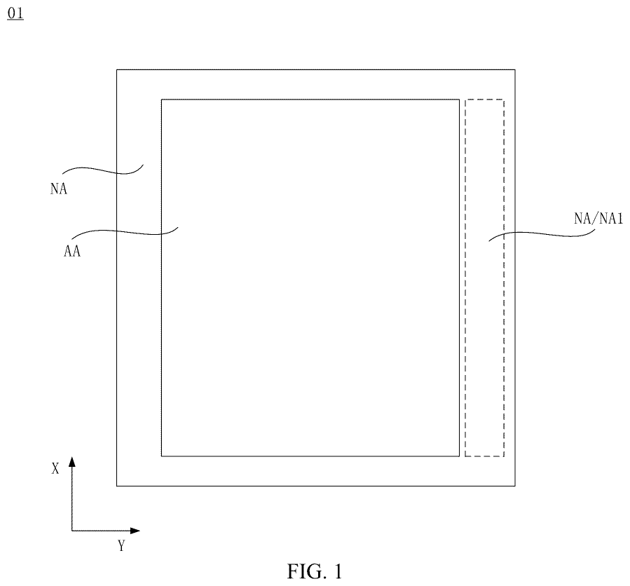

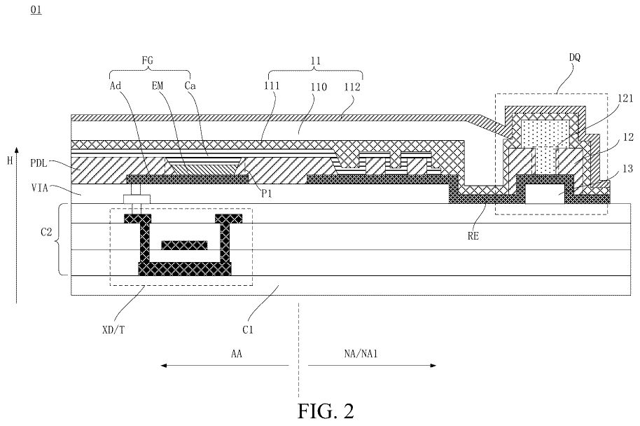

FIG. 1 is a schematic plan view of a display panel according to an embodiment of the present disclosure, and FIG. 2 is a schematic structural view of the display panel according to an embodiment of the present disclosure.

As shown in FIG. 1, the display panel 01 includes a display region AA and a non-display region NA surrounding the display region AA, and the non-display region NA includes a first non-display region NA1 located at a side of the display region AA. As shown in FIG. 2, the non-display region NA includes a barrier structure DQ and a first electrode RE. Both the barrier structure DQ and the first electrode RE can be located in the first non-display region NA1, and the barrier structure DQ overlaps with the first electrode RE in a thickness direction H of the display panel 01.

The display panel 01 further includes an encapsulation structure 11, which includes an organic material 110, and a first inorganic layer 111 and a second inorganic layer 112 located at two opposite sides of the organic material 110. The encapsulation structure 11 can encapsulate the display region AA and the non-display region NA to prevent external water and oxygen. In the thickness direction H of the display panel 01, the organic material 110 covers the display region AA, and can flow from the display region AA to the barrier structure DQ, and the barrier structure DQ is configured to block the overflow of the organic material 110, so as to prevent the organic material 110 from flowing to an edge of the display panel 01, thereby preventing external water and oxygen from entering the display panel 01 through the organic material 110. The first electrode RE can be configured to transmit a power signal to the display region AA.

The barrier structure DQ includes a first portion 12, which is located at a side of the first electrode RE facing a light-exiting surface of the display panel 01. The first portion 12 includes a hollow region 121 in which the first electrode RE is exposed. That is, the first electrode RE exposed in the hollow region 121 can be observed when viewed from a side of the first portion 12 away from the first electrode RE. A light-transmitting film layer located at a side of the first portion 12, which faces the light-exiting surface of the display panel 01, can fill the hollow region 121.

In an example, the first portion 12 has a black color.

In the related art, an encapsulation effect of the display panel can be judged by observing whether the organic material overflows beyond the barrier structure, and an overflow situation of the organic material is usually checked by using a color change at the edges of an inner side and an outer side of the barrier structure. However, when the barrier structure includes the black first portion, the edges of the inner side and the outer side of the barrier structure have a black color, making it difficult to visually observe an overflow position of the organic material. Even if the organic material overflows the barrier structure, it cannot be detected, thereby affecting the quality of the product.

In the embodiments of the present disclosure, the first electrode RE is exposed in the hollow region 121 of the first portion 12. In this case, when the organic material 110 overflows to the position of the hollow region 121 of the barrier structure DQ, the film layer at a side of the first electrode RE facing the light-exiting surface of the display panel 01 changes in the hollow region 121, then the first electrode RE has different retroreflective brightness. Therefore, the overflow situation of the organic material 110 can be visually observed, thereby achieving a function of monitoring the overflow situation of the organic material 110.

It should be noted that for a barrier structure of which the first portion does not have a black color, the overflow situation of the organic material can also be observed by utilizing the solutions provided in the present disclosure.

Referring to FIG. 2, in an embodiment of the present disclosure, the display region AA is provided with a display element FG, which includes a driving electrode Ad, a light-emitting material EM, and a second electrode Ca which is located at a side of the driving electrode Ad facing the light-exiting surface of the display panel 01. The display element FG can be an organic light emitting diode.

The driving electrode Ad can be an anode of the display element FG, and the second electrode Ca can be a cathode of the display element FG. The holes generated by the driving electrode Ad and electrons generated by the second electrode Ca meet in the light-emitting material EM to form excitons, thereby generating light emission.

Further, as shown in FIG. 2, the display panel 01 further includes a substrate C1 and a transistor array layer C2 located at a side of the substrate C1. The transistor array layer C2 includes a pixel circuit XD, which includes a plurality of transistors T and is electrically connected to the driving electrode Ad of the display element FG for providing a light-emitting driving current to the display element FG.

The first electrode RE in the non-display region NA is electrically connected to the second electrode Ca, for transmitting a power signal, for example, a cathode electrical signal to the second electrode Ca in the display region AA. The first electrode RE extends through the barrier structure DQ.

The first electrode RE and the driving electrode Ad are formed in a same layer. That is, the first electrode RE located in the non-display region NA can be made of the same material as the driving electrode Ad in the display region AA. The first electrode RE can be a laminated structure of indium tin oxide/silver/indium tin oxide (ITO/Ag/ITO).

In the embodiments of the present disclosure, the first electrode RE capable of transmitting the power signal is exposed in the hollow region 121 of the first portion 12, and thus there is no need to additionally form an electrode for reflecting light to observe the overflow situation of the organic material 110, thereby being beneficial to reducing the manufacture cost of the display panel 01.

Referring to FIG. 2, in an embodiment of the present disclosure, the display region AA is further provided with a pixel definition layer PDL, which is configured to define a position of the display element FG. The pixel definition layer PDL is located at a side of the driving electrode Ad away from the substrate C1. In the manufacturing process of the display panel 01, the pixel definition layer PDL can be formed after the driving electrode Ad is formed.

The pixel definition layer PDL includes first openings P1, and in one of the first openings P1, the light-emitting material EM of a respective display element FG is located, thereby defining the position of the display element FG. The second electrode Ca of the display element FG can be located at a side of the pixel definition layer PDL away from the substrate C1.

In an example, the pixel definition layer PDL has a black color. In this way, reflection of external ambient light in the display panel 01 can be reduced, which is beneficial to improving the display quality.

The first portion 12 and the pixel definition layer PDL are formed in a same layer. That is, the first portion 12 can be formed using the same material and process as the pixel definition layer PDL. When the pixel definition layer PDL has a black color, the first portion 12 also has a black color.

It can be understood that, in the display panel 01, the barrier structure DQ can include one film layer or a plurality of film layers, and the first portion 12 is one film layer in the barrier structure DQ.

In the embodiments of the present disclosure, the pixel definition layer PDL and the first portion 12 of the barrier structure DQ are formed in a same layer, which is beneficial to simplifying the manufacturing process of the barrier structure DQ, thereby reducing the manufacturing difficulty of the barrier structure DQ.

In addition, as shown in FIG. 2, a planarization layer VIA is further provided between the transistor array layer C2 and the driving electrode Ad. The barrier structure DQ can further include a second portion 13 in the same layer as the planarization layer VIA to ensure that the barrier structure DQ has a sufficient height to block the overflow of the organic material 110. In the barrier structure DQ, the first electrode RE can be located between the first portion 12 and the second portion 13.

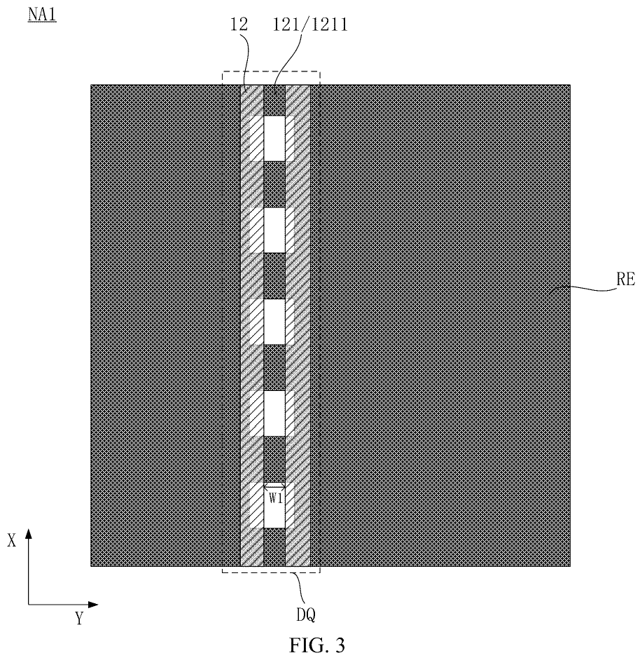

FIG. 3 is a partial plan view of the first non-display region in FIG. 1.

In an embodiment of the present disclosure, as shown in FIG. 1 and FIG. 3, the non-display region NA includes a first non-display region NA1 located at a side of the display region AA, and the barrier structure DQ is located in the first non-display region NA1. An extending direction of the barrier structure DQ intersects with an arrangement direction in which the display region AA and the first non-display region NA1 are arranged.

The hollow region 121 of the first portion 12 includes a first hollow region 1211 extending in a first direction X, which is an extending direction of the barrier structure DQ.

In an example, the display region AA and the first non-display region NA1 are arranged in a second direction Y, which intersects with a first direction X. The second direction Y can be a row direction of the display panel 01, and the first direction X can be a column direction of the display panel 01. Or, the second direction Y can be a column direction of the display panel 01, and the first direction X can be a row direction of the display panel 01.

It should be noted that, FIG. 3 merely illustrates a film layer relationship between the first portion 12 and the first electrode RE in the first non-display region NA1 for the clarity of illustration. A light-transmitting film layer, such as a support pillar film layer, can be arranged at a side of the first portion 12 facing the light-exiting surface of the display panel 01, and can fill the hollow region 121 of the first portion 12.

In the embodiments of the present disclosure, the extending direction of the first hollow region 1211 is set to be consistent with the extending direction of the barrier structure DQ, so that the monitoring range of the overflow situation of the organic material 110 can be increased. In this case, it is beneficial to making the organic material 110 always flow to the first hollow region 1211 when overflowing at different positions of the barrier structure DQ, thereby being visually recognized, and further being beneficial to realizing comprehensive monitoring of the overflow of the organic material 110.

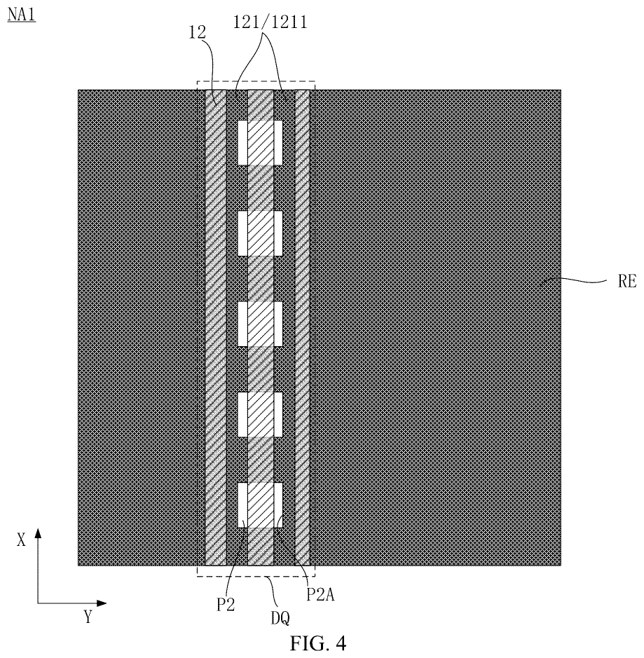

FIG. 4 is another partial plan view of the first non-display region in FIG. 1.

In an embodiment of the present disclosure, as shown in FIG. 4, in a same barrier structure DQ, the first portion 12 includes a plurality of first hollow regions 1211 arranged in the second direction Y. The second direction Y intersects with the first direction X. The second direction Y can be the arrangement direction in which the display region AA and the first non-display region NA1 are arranged.

In the embodiments of the present disclosure, a same barrier structure DQ includes a plurality of first hollow regions 1211. In this case, when the organic material 110 overflows, the organic material 110 flows from the first hollow region 1211 close to the display region AA to the first hollow region 1211 away from the display region AA. On the one hand, the overflow position of the organic material 110 can be observed according to the position of each first hollow region 1211, thereby being beneficial to achieve fine monitoring of the overflow situation of the organic material 110. On the other hand, when the organic material 110 overflows to a certain first hollow region 1211 and odes not overflow to another first hollow region 1211, in the two first hollow regions 1211, film layers arranged at a side of the first electrode RE facing the light-exiting surface of the display panel 01 have different structures. One of the two first hollow regions is covered by the organic material, and another one of the two first hollow regions is not covered by the organic material. Therefore, the overflow position of the organic material 110 can be determined by comparing the difference of the retroreflective brightness of the first electrode RE in the two first hollow regions 1211, thereby being beneficial to reducing the difficulty of visually recognizing the overflow situation of the organic material 110.

In an example, as shown in FIG. 3 and FIG. 4, the first hollow region 1211 is a continuous structure. Further, the length of the first hollow region 1211 can be the same as that of the barrier structure DQ. In this way, when the organic material 110 overflows at any position of the barrier structure DQ, the organic material 110 passes through the position of the first hollow region 1211, thereby being visually recognized.

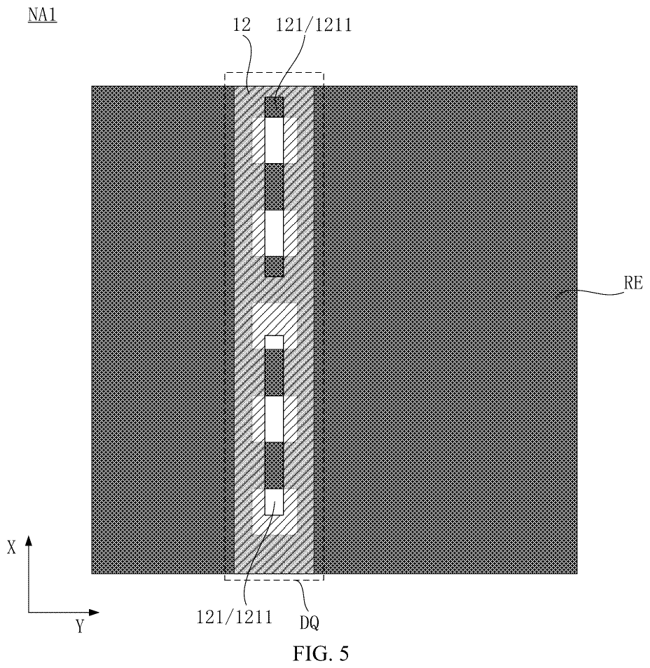

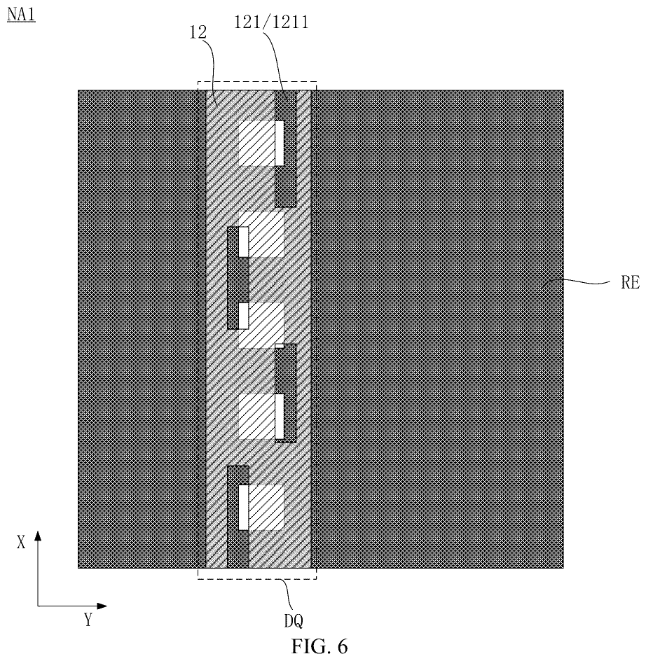

FIG. 5 is another partial plan view of the first non-display region in FIG. 1; and FIG. 6 is another partial plan view of the first non-display region in FIG. 1.

In the embodiments of the present disclosure, as shown in FIG. 5 and FIG. 6, the first hollow region 1211 is a discontinuous structure. That is, the first hollow region 1211 can include a plurality of noncontiguous portions. The extension direction of each portion can be the same as that of the barrier structure DQ.

In an example, as shown in FIG. 5, a connection line between portions of the first hollow region 1211 can be a straight line. In an example, as shown in FIG. 6, the connection line between portions of the first hollow region 1211 can be a poly line. In this case, the extending direction of the first hollow region 1211 is macroscopically the same as the extending direction of the barrier structure DQ.

In an example, the portions of the first hollow region 1211 are uniformly distributed in the barrier structure DQ.

According to an embodiment of the present disclosure, the structure diversity of the first hollow region 1211 can be increased, and the structure of the first hollow region 1211 can be flexibly configured according to requirements to meet different requirements for overflow monitoring of the organic material.

It should be noted that, for the clarity of illustration, FIGS. 4-6 merely illustrate the film layer relationship between the first portion 12 and the first electrode RE in the first non-display region NA1. A light-transmitting film layer, such as a support pillar film layer, can be provided at a side of the first portion 12 facing the light-exiting surface of the display panel 01, and can fill the hollow region 121 in the first portion 12.

In the embodiments of the present disclosure, further referring to FIG. 3, a width of the first hollow region 1211 in the second direction Y is W1, where 5 μm≤W1≤10 μm. Of course, the width of the first hollow region 1211 in the second direction Y is smaller than that of the barrier structure DQ in the second direction Y. The second direction Y intersects with the first direction X.

In an example, the first direction X is a column direction of the display panel 01, and the second direction Y is a row direction of the display panel 01.

In the embodiments of the present disclosure, the width of the first hollow region 1211 in the second direction Y is arranged to be within a preset range, so that the width of the first hollow region 1211 can be prevented from being too large to affect the structural stability of the barrier structure DQ. On the other hand, the first electrode RE in the first hollow region 1211 can have a sufficiently large reflective region, which is beneficial for observing the reflective condition of the first electrode RE on the side of the first portion 12 away from the first electrode RE, thereby beneficial to visually identifying the overflow situation of the organic material 110.

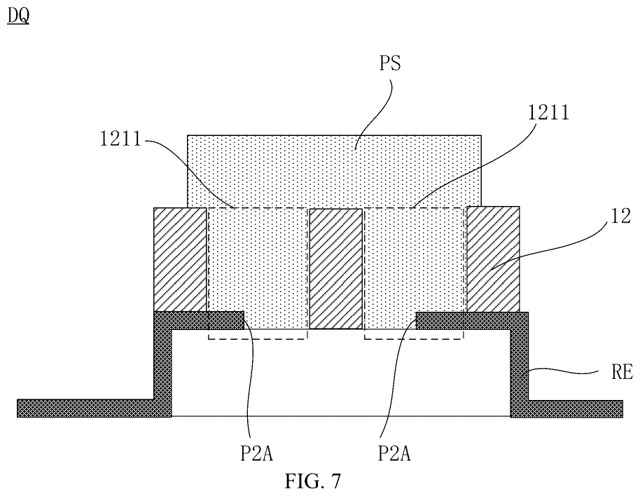

FIG. 7 is a schematic view of a barrier structure according to an embodiment of the present disclosure.

In an embodiment of the present disclosure, referring to FIG. 4 and FIG. 7, the first electrode RE includes a plurality of second openings P2, and an edge P2A of at least part of the second openings P2 is exposed in the first hollow region 1211.

The first electrode RE generally has a large area, and before the first electrode RE is formed, some organic film layers, such as a planarization layer VIA described in the above embodiments, are usually formed. That is, an organic film layer is formed at a side of the first electrode RE facing the substrate C1. Therefore, in order to avoid the peeling phenomenon of the first electrode RE caused by gas in the organic film layer, the second opening P2 is formed in the first electrode RE, so that the gas in the organic film layer can be discharged from the second opening P2, thereby improving the stability of the first electrode RE.

It can be understood that the edge P2A of the second opening P2 is a boundary between a solid portion of the first electrode RE and the second opening P2. When the film layer facing the light-exiting surface of the display panel 01 at the edge of the second opening P2 changes, the retroreflective brightness at the edge P2A of the second opening P2 changes greatly.

In the embodiments of the present disclosure, the edge P2A of at least part of the second opening P2 is exposed in the first hollow region 1211. In this case, when the organic material 110 overflows to the first hollow region 1211, the brightness at the edge P2A of the second opening P2 changes obviously, thereby being beneficial to easily observing the overflow situation of the organic material 110.

Further, referring to FIG. 7, the edge P2A of the second opening P2 can be exposed in each of plurality of first hollow regions 1211. In this case, the overflow position of the organic material 110 can be determined by comparing and observing the retroreflective brightness difference at the edge P2A of the second opening P2 in each first hollow region 1211, thereby being beneficial to easily visually recognizing the overflow situation of the organic material.

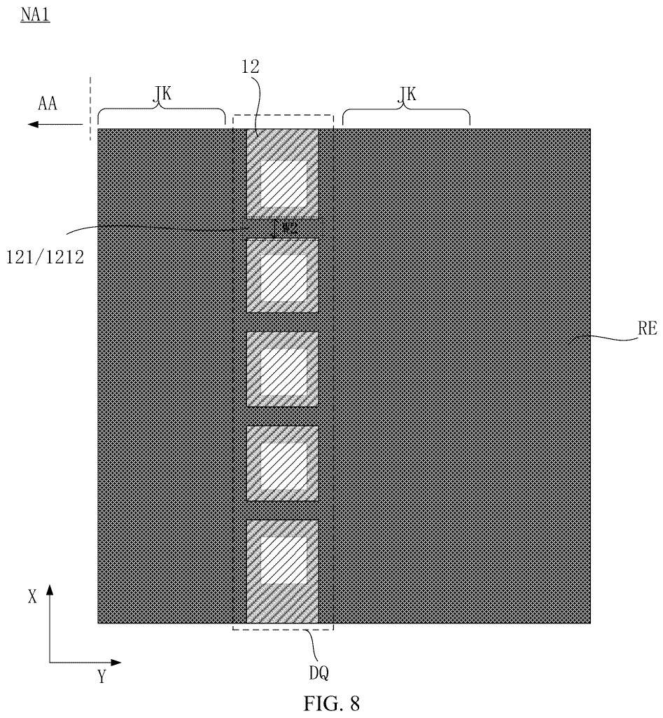

FIG. 8 is another partial plan view of the first non-display region in FIG. 1.

In the embodiments of the present disclosure, as shown in FIG. 8, the hollow region 121 of the first portion 12 includes a second hollow region 1212 extending in the second direction Y, which intersects the first direction X. And the barrier structure DQ extends in the first direction X.

The second direction Y can be the arrangement direction in which the display region AA and the first non-display region NA1 are arranged.

In an example, the first direction X is the column direction of the display panel 01, and the second direction Y is the row direction of the display panel 01. Or, the first direction X can be the row direction of the display panel 01, and the second direction Y is the column direction of the display panel 01.

In the embodiments of the present disclosure, the extending direction of the second hollow region 1212 intersects with the extending direction of the barrier structure DQ, so that the structural diversity of the hollow region 121 can be increased to enrich the structural design of the display panel 01, and the overflow situation of the organic material 110 is monitored. Moreover, the extending direction of the second hollow region 1212 intersects with the extending direction of the barrier structure DQ, so that the area of the second hollow region 1212 can be prevented from being too large while ensuring that the first electrode RE in the second hollow region 1212 has a sufficient exposed area, thereby being beneficial to improving the stability of the barrier structure DQ.

It should be noted that, FIG. 8 merely illustrates a film layer relationship between the first portion 12 and the first electrode RE in the first non-display region NA1 for the clarity of illustration. A light-transmitting film layer, such as a support pillar film layer, can be provided at a side of the first portion 12 facing the light-exiting surface of the display panel 01, and can fill the hollow region 121 in the first portion 12.

Referring to FIG. 8, in the embodiments of the present disclosure, the second hollow region 1212 penetrates through the first portion 12 in the second direction Y. That is, in the barrier structure DQ, the edge of the first portion 12 facing the display region AA is no longer a continuous structure, but is separated by the second hollow region 1212; and the edge of the first portion 12 away from the display region AA is no longer a continuous structure, but is separated by the second hollow region 1212.

When the first portion 12 has a black color, the edge of the side of the barrier structure DQ close to the display region AA is no longer continuous black, and the edge of the barrier structure DQ away from the display region AA is no longer continuous black.

As shown in FIG. 8, clearance regions JK are disposed at two opposite sides of the barrier structure DQ in the second direction Y, and there is a step between the clearance region JK and the barrier structure DQ. When the organic material 110 does not overflow to the edge of the barrier structure DQ, the color at the edge of the barrier structure DQ includes not only a color of the first portion 12, but also a color caused by the step between the barrier structure DQ and the clearance region JK close thereto. When the organic material 110 overflows to the edge of the barrier structure DQ, the organic material 110 can fill the step between the barrier structure DQ and the clearance region JK, to change the color of the edge of the barrier structure DQ at this position. Thus, the color of the edge of the barrier structure DQ is no longer continuous black, thereby visually recognizing the overflow situation of the organic material. Herein, the edge of the barrier structure DQ refers to an edge of the barrier structure DQ close to the display region AA or an edge of the barrier structure DQ away from the display region AA.

It should be noted that, the side of the first portion 12 facing the light-exiting surface of the display panel 01 can also be provided with other light-transmitting film layers, such as a support pillar film layer. The film layer can be filled into the second hollow region 1212 to ensure the blocking effect of the barrier structure DQ.

In an example, referring to FIG. 8, the hollow region 121 of the first portion 12 includes a plurality of second hollow regions 1212 arranged in the first direction X. Each second hollow region 1212 can penetrate through the first portion 12 in the second direction Y. In this way, when the organic material 110 overflows to the edge of the barrier structure DQ, the black color at the edge of the barrier structure DQ can be non-continuous at some positions, thereby facilitating visual observation of the overflow situation of the organic material 110.

In an embodiments of the present disclosure, as shown in FIG. 8, the width of the second hollow region 1212 in the first direction X is W2, where 5 μm≤W2≤10 μm. The first direction X can be an extending direction of the barrier structure DQ.

In the embodiments of the present disclosure, the width of the second hollow region 1212 in the first direction X is set to be within a preset range. On the one hand, the first electrode RE in the second hollow region 1212 can have a sufficiently large reflective area, which is beneficial to observe the reflective condition of the first electrode RE at a side of the first portion 12 away from the first electrode RE, thereby being beneficial to visually recognizing the overflow situation of the organic material 110; and on the other hand, it can avoid the excessive width of the second hollow region 1212, which would affect the structural stability of the barrier structure DQ.

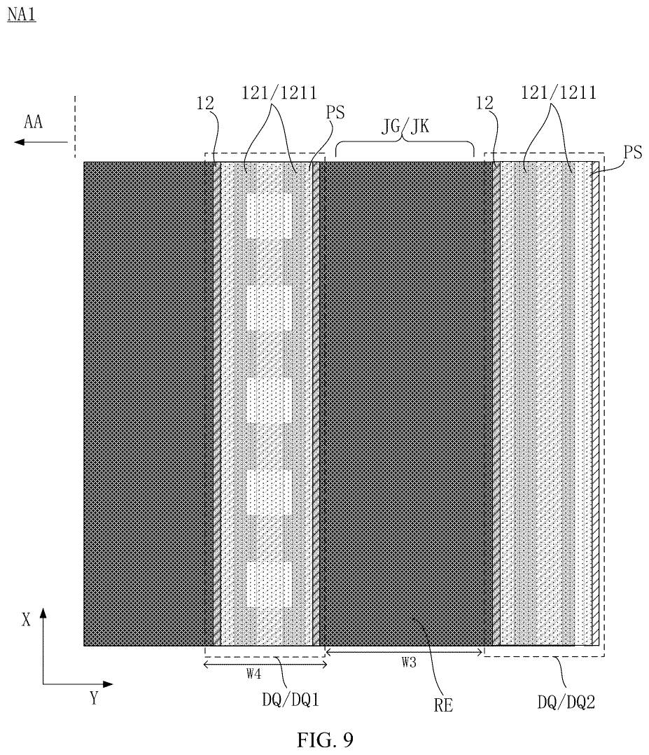

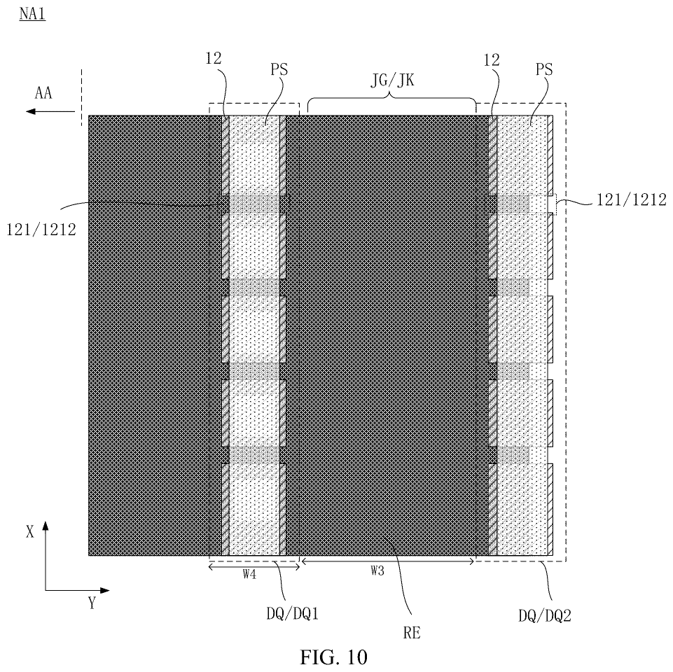

FIG. 9 is another partial plan view of the first non-display region in FIG. 1, and FIG. 10 is another partial plan view of the first non-display region in FIG. 1.

In an embodiment of the present disclosure, as shown in FIG. 9 and FIG. 10, the hollow region 121 of the first portion 12 includes a first hollow region 1211 and/or a second hollow region 1212. That is, in the first portion 12 of the barrier structure DQ, only the first hollow region 1211, or only the second hollow region 1212 can be provided, or both the first hollow region 1211 and the second hollow region 1212 can be provided. FIG. 9 only illustrates a case that the first portion 12 includes the first hollow region 1211, and FIG. 10 only illustrates a case that the first portion 12 includes the second hollow region 1212.

The first hollow region 1211 extends in the first direction X, which is an extending direction of the barrier structure DQ. The second hollow region 1212 extends in the second direction Y, which intersects the first direction X.

In an example, the first direction X is the column direction of the display panel 01, correspondingly, the second direction Y is the row direction of the display panel 01. Or, the first direction X is the row direction in the display panel 01, correspondingly, the second direction Y is the row direction in the display panel 01.

The non-display region NA includes a plurality of barrier structures DQ, which includes a first barrier DQ1 and a second barrier DQ2. The first wall DQ1 and the second barrier DQ2 are located at a same side of the display region AA. For example, as shown in FIG. 9 and FIG. 10, the first barrier DQ1 and the second barrier DQ2 are both located in the first non-display region NA1 at one side of the display region AA. The first barrier DQ1 and the second barrier DQ2 can be arranged in the second direction Y.

The first barrier DQ1 includes at least one of the first hollow region 1211 and the second hollow region 1212, and the second barrier DQ2 includes at least one of the first hollow region 1211 and the second hollow region 1212. That is, each of the first barrier DQ1 and the second barrier DQ2 is provided with the hollow region 121.

In the embodiments of the present disclosure, a plurality of barrier structures DQ are disposed in the non-display region NA located at one side of the display region AA. In this case, after the organic material 110 overflows beyond more than one barrier structure DQ, other barrier can block the overflow of the organic material 110, thereby effectively preventing external water and oxygen from entering the interior of the display panel 01 through the organic material 110, and thus improving a blocking effect on the overflow of the organic material 110.

In addition, each of the first barrier DQ1 and the second barrier DQ2 is provided with the hollow region 121. In this way, on the one hand, the monitoring range of the overflow situation of the organic material 110 can be improved; and on the other hand, the retroreflective brightness of the first electrode RE in the hollow region 121 of the first barrier DQ1 and the retroreflective brightness of the first electrode RE in the hollow region 121 of the second barrier DQ2 can be observed by comparison, making it more easily to observe the overflow situation of the organic material 110, thereby reducing the difficulty of visually monitoring the overflow of the organic material 110.

Still referring to FIG. 9 and FIG. 10, in the embodiments of the present disclosure, the first barrier DQ1 is located at a side of the second barrier DQ2 close to the display region AA, and the organic material 110 flows from the first barrier DQ1 to the second barrier DQ2 when the organic material 110 overflows.

A spacing region JG is between the first barrier DQ1 and the second barrier DQ2, and the spacing region JG can be a clearance region JK, in which no organic film layer is provided. There is a step between the first barrier DQ1 and the spacing region JG, and there is a step between the second barrier DQ2 and the spacing region JG.

A width W3 of the spacing region JG in the second direction Y is not less than a width W4 of the first barrier DQ1 in the second direction Y. The width W3 of the spacing region JG in the second direction Y can be not less than the width of the second barrier DQ2 in the second direction Y.

In the embodiments of the present disclosure, the spacing region JG is arranged between the first barrier DQ1 and the second barrier DQ2, the organic material 110 flows into the spacing region JG after the organic material 110 overflows beyond the first barrier DQ1, thereby being beneficial to reducing the overflow capability of the organic material 110, and enabling the second barrier DQ2 to block the organic material 110 effectively, and thus improving the blocking effect on the overflow of the organic material 110. Meanwhile, the width of the spacing region JG is set to be within a certain range. On one hand, it is beneficial to improving the buffering effect of the spacing region JG on the overflow the organic material 110. On the other hand, it can avoid a problem that a distance between the first barrier DQ1 and the second barrier DQ2 is too small, which would make it difficult to achieve simultaneous manufacture of the first barrier DQ1 and the second barrier DQ2 in the process.

It should be noted that the width of the spacing region JG in the second direction Y should not be too large to avoid affecting the narrow frame requirements of the display panel 01.

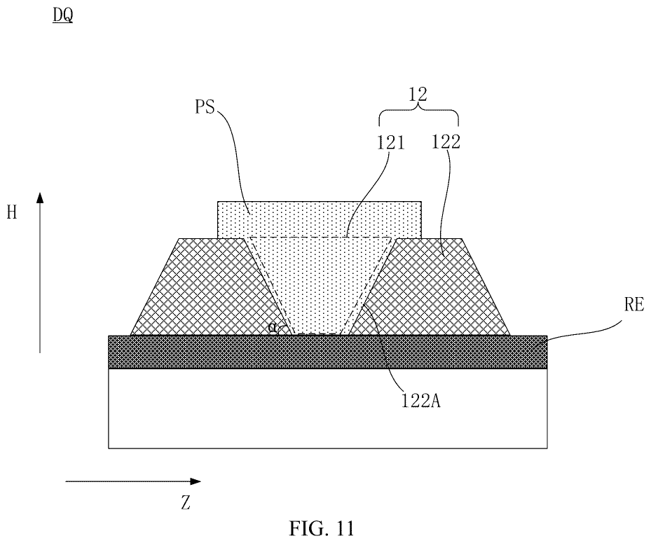

FIG. 11 is a schematic view of another barrier structure according to an embodiment of the present disclosure.

In an embodiment of the present disclosure, as shown in FIG. 11, the first portion 12 further includes a solid portion 122 adjacent to the hollow region 121 in the width direction Z of the hollow region 121. When the hollow region 121 is the first hollow region 1211 extending in the first direction X, the width direction Z thereof is a direction perpendicular to the first direction X and can be the second direction Y. When the hollow region 121 is the second hollow region 1212 extending along the second direction Y, the width direction Z thereof is a direction perpendicular to the second direction Y and can be the first direction X.

The solid portion 122 includes a first side surface 122A adjacent to the hollow region 121. The first side surface 122A is a boundary between the solid portion 122 and the hollow region 121. An angle between the first side surface 122A and a plane where the display panel 01 is located is a first angle a, and an opening of the first angle a faces the solid portion 122, where 35°≤a≤45°.

In the embodiments of the present disclosure, an angle of the first angle a is set to be within a range from 35° to 45°, which can make the side surface of the solid portion 122 connecting to the hollow region 121 relatively flat, which is conducive to the continuity of the subsequent film layer, thereby avoiding the fracture of the subsequent film layer at the first side surface 122A. Moreover, it is beneficial for the subsequent film layer to fill the hollow region 121 to ensure the barrier effect of the barrier structure DQ on the organic material 110. In particular, when the hollow region 121 is the second hollow region 1212 penetrating through the first portion 12, the subsequent film layer can fully fill the second hollow region 1212 to prevent the organic material 110 from overflowing through the second hollow region 1212.

In addition, the angle of the first angle a is set to be within a preset range, so that the hollow region 121 can form a structure of “upper portion being wider and lower portion being narrower” (that is, an area of the part of the hollow region 121 close to the substrate C1 is smaller and an area of the part of the hollow region 121 away from the substrate C1 is larger), which is beneficial to increasing an observation angle for the first electrode RE exposed in the hollow region 121, thereby improving the convenience of monitoring the overflow situation of the organic material 110.

In an embodiment of the present disclosure, as shown in FIGS. 9-11, the barrier structure DQ further includes a support pillar PS located at a side of the first portion 12 facing the light-exiting surface of the display panel 01. The support pillar PS can be used to support a mask, to prevent the mask from damaging the already-formed film layer when forming a subsequent film layer. The support pillar PS is a light-transmitting film layer.

In the thickness direction H of the display panel 01, the support pillar PS overlaps at least part of the hollow region 121. The support pillar PS can be arranged at the first portion 12 and fill the hollow region 121 of the first portion 12. That is, the support pillar PS can be further formed after completing the manufacture of the first portion 12.

In the embodiments of the present disclosure, the barrier structure DQ is further provided with a support pillar PS. On one hand, the height of the barrier structure DQ can be increased, and the blocking effect of the barrier structure DQ on the organic material 110 is improved; and on the other hand, the support pillar PS can be used to fill the hollow region 121 of the first portion 12, thereby preventing the organic material 110 from overflowing from the hollow region 121.

In an embodiment of the present disclosure, referring to FIG. 4 and FIG. 7, at least part of the edge of the first electrode RE is exposed in the hollow region 121, and the support pillar PS at least partially overlaps with the hollow region 121 and the edge of the first electrode RE in the thickness direction H of the display panel 01.

That is, the edge of the first electrode RE exposed in the hollow region 121 can overlap with the support pillar PS. When the support pillar PS fills the hollow region 121, the edge of the first electrode RE in the hollow region 121 can be covered.

It can be seen from the above analysis that the first electrode RE can be a laminated structure of indium tin oxide/silver/indium tin oxide (ITO/Ag/ITO). At the edge of the first electrode RE, a side surface of the metal silver is not provided with indium tin oxide for protection, but is in an exposed state.

In the embodiments of the present disclosure, the support pillar PS overlaps with the edge of the first electrode RE exposed in the hollow region 121. In this case, the support pillar PS can be used to protect the edge of the first electrode RE, thereby preventing the material in the first electrode RE from being corroded in the subsequent process of the display panel 01, for example, the edge of the first electrode RE being laterally etched. In this way, it is beneficial to improving the structural stability of the first electrode RE.

In the embodiments of the present disclosure, the edge of the first electrode RE includes not only the edge P2A of the second opening P2, but also tan outer edge of the first electrode RE.

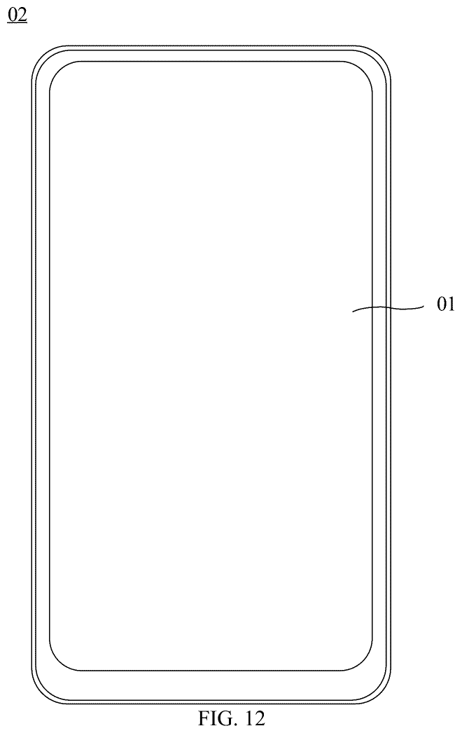

FIG. 12 is a schematic view of a display device according to an embodiment of the present disclosure.

An embodiment of the present disclosure provides a display device 02. As shown in FIG. 12, the display device 02 includes a display panel 01. Exemplarily, the display device 02 may be an electronic device such as a computer, a television, a mobile phone, and a vehicle-mounted display, which is not specifically limited in the present disclosure.

In the display device 02, the first electrode RE is exposed in the hollow region 121 of the first portion 12. In this case, in the hollow region 121, the film layer at a side of the first electrode RE facing the light-exiting surface of the display panel 01 changes when the organic material 110 overflows to the position of the hollow region 121 of the barrier structure DQ, and the first electrode RE has different retroreflective brightness. Therefore, the overflow situation of the organic material 110 can be visually observed, thereby achieving an effect of monitoring the overflow situation of the organic material 110.

The above-described embodiments are merely preferred embodiments of the present disclosure and are not intended to limit the present disclosure. Any modifications, equivalent substitutions and improvements made within the principle of the present disclosure shall fall into the protection scope of the present disclosure.

What is claimed is:

1. A display panel, comprising a display region and a non-display region surrounding the display region;
wherein the display panel comprises an encapsulation structure comprising an organic material, and the organic material covers the display region in a thickness direction of the display panel;
the non-display region is provided with a barrier structure and a first electrode, the barrier structure overlaps with the first electrode in the thickness direction of the display panel; and
the barrier structure comprises a first portion located at a side of the first electrode facing a light-exiting surface of the display panel, and the first portion comprises a hollow region, in which the first electrode is exposed.

2. The display panel as described in claim 1, wherein
the display region is provided with a display element; the display element comprises a driving electrode, a light-emitting material and a second electrode that are stacked; and the second electrode is located at a side of the driving electrode facing the light-exiting surface of the display panel, and
the first electrode is configured to transmit a power signal to the second electrode, and the first electrode and the driving electrode are formed in a same layer.

3. The display panel as described in claim 2, wherein
the display region is further provide with a pixel definition layer comprising first openings, and a light-emitting material of the display element is located in the first openings, and
the first portion and the pixel definition layer are formed in a same layer.

4. The display panel as described in claim 1, wherein the hollow region of the first portion comprises a first hollow region extending in a first direction, which is an extending direction of the barrier structure.

5. The display panel as described in claim 4, wherein for a same barrier structure, the first portion comprises first hollow regions arranged in a second direction, which intersects with the first direction.

6. The display panel as described in claim 4, wherein a length of the first hollow region is the same as a length of the barrier structure.

7. The display panel as described in claim 4, wherein the first hollow region is formed as a discontinuous structure.

8. The display panel as described in claim 4, wherein the first electrode comprises second openings, and at least part of edges of the second openings is exposed in the first hollow region.

9. The display panel as described in claim 4, wherein a width of the first hollow region in a second direction is W1, where 5 μm≤W1≤10 μm, and the second direction intersects with the first direction.

10. The display panel as described in claim 1, wherein the hollow region of the first portion comprises a second hollow region, the barrier structure extends in a first direction, and the second hollow region extends in a second direction intersecting with the first direction.

11. The display panel as described in claim 10, wherein the hollow region of the first portion comprises second hollow regions arranged in the first direction.

12. The display panel as described in claim 10, wherein the second hollow region penetrates through the first portion in the second direction.

13. The display panel as described in claim 10, wherein a width of the second hollow region in the first direction is W2, where 5 μm≤W2≤10 μm.

14. The display panel as described in claim 1,
wherein the hollow region of the first portion comprises a first hollow region extending in a first direction, which is an extending direction of the barrier structure, and/or a second hollow region extending in a second direction intersecting with the first direction;
the non-display region is provided with a plurality of the barrier structures comprising a first barrier and a second barrier, which are located at a same side of the display region; and
the first barrier comprises at least one of the first hollow region or the second hollow region, and the second barrier comprises at least one of the first hollow region or the second hollow region.

15. The display panel as described in claim 14, wherein the first barrier is located at a side of the second barrier close to the display region, a spacing region is formed between the first barrier and the second barrier, and a width of the spacing region in the second direction is not less than a thickness of the first barrier in the second direction.

16. The display panel as described in claim 1, wherein the first portion further comprises a solid portion adjacent to the hollow region in a width direction of the hollow region; the solid portion comprises a first side surface adjacent to the hollow region, an angle between the first side surface and a plane where the display panel is located is a first angle a, and an opening of the first angle a faces the solid portion of the first portion, where 35°≤a≤45°.

17. The display panel as described in claim 1, wherein the barrier structure further comprises a support pillar located at a side of the first portion facing the light-exiting surface of the display panel, and the support pillar overlaps with at least part of the hollow region in the thickness direction of the display panel.

18. The display panel as described in claim 17, wherein at least part of an edge of the first electrode is exposed in the hollow region, and in the thickness direction of the display panel, the support pillar at least partially overlaps with the hollow region and an edge of the first electrode.

19. A display device, comprising a display panel, wherein the display panel comprises a display region and a non-display region surrounding the display region;
wherein the display panel comprises an encapsulation structure comprising an organic material, and the organic material covers the display region in a thickness direction of the display panel;
the non-display region is provided with a barrier structure and a first electrode, the barrier structure overlaps with the first electrode in the thickness direction of the display panel; and
the barrier structure comprises a first portion located at a side of the first electrode facing a light-exiting surface of the display panel, and the first portion comprises a hollow region, in which the first electrode is exposed.
